(19) United States
(12) Patent Application Publication
(10) Pub. No.: US 2020/0105782 A1
(43) Pub. Date: Apr. 2, 2020

(54) VERTICAL CHANNEL STRUCTURE AND MEMORY DEVICE

(71) Applicant: MACRONIX International Co., Ltd., Hsinchu (TW)

(72) Inventors: Jung-Yi Guo, Hsinchu County (TW); Chun-Min Cheng, Hsinchu City (TW)

(73) Assignee: MACRONIX International Co., Ltd., Hsinchu (TW)

(21) Appl. No.: 16/147,065

(22) Filed: Sep. 28, 2018

(51) Int. Cl. H01L 27/11582; H01L 21/225

(52) U.S. Cl. CPC H01L 27/11582; H01L 29/0684; H01L 21/2255

(57) ABSTRACT

A vertical channel structure including a substrate, a stack structure, and a channel structure is provided. The stack structure is disposed on the substrate. The channel structure is disposed in an opening that at least partially penetrates through the stack structure. The channel structure includes a first channel layer and a second channel layer. The first channel layer is disposed on a bottom of the opening. The second channel layer is disposed on the first channel layer. A resistance value of the first channel layer is less than a resistance value of the second channel layer.

### BACKGROUND

### Technical Field

The invention relates to a vertical channel structure and a memory device.

### Description of Related Art

With the continuous development of science and technology, the demands for greater storage capacity also increase as electronic devices continue to improve. To satisfy the demands for high storage density, memory devices become smaller in size and have higher integrity. Therefore, the form of memory devices has developed from 2D memory devices having a planar gate structure to 3D memory devices having a vertical channel (VC) structure. However, the 3D memory device having the vertical channel structure still faces many challenges.

### SUMMARY

The invention provides a vertical channel structure and a memory device, which is able to reduce the string resistance value of the channel layer that is not controlled by the gate (word line), thereby enhancing the conductivity of the vertical channel structure.

The invention provides a vertical channel structure including a substrate, a stack structure and a channel structure. The stack structure is disposed on the substrate. The channel structure is disposed in openings that penetrate at least partially through the stack structure. The channel structure includes a first channel layer and a second channel layer. The first channel layer is disposed on the bottom of the openings. The second channel layer is located on the first channel layer. The resistance value of the first channel layer is smaller than the resistance value of the second channel layer.

The present invention provides a memory device comprising a substrate, a first stack structure, a second stack structure, a channel structure, and a charge storage layer. The first stack structure is disposed on the substrate. The second stack structure is disposed on the first stack structure. The second stack structure includes a plurality of conductive layers and a plurality of dielectric layers which are alternately stacked. The channel structure includes a first channel layer and a second channel layer. The first channel layer is embedded in the first stack structure. The second channel layer is located on the first channel layer and is embedded in the second stack structure. The resistance value of the first channel layer is smaller than the resistance value of the second channel layer. The charge storage layer is disposed between the second stack structure and the second channel layer.

The present invention provides another memory device including: a substrate, a first stack structure, a second stack structure, a channel structure, and a charge storage layer. The first stack structure is disposed on the substrate. The second stack structure is disposed on the first stack structure. The second stack structure includes a plurality of conductive layers and a plurality of dielectric layers which are alternately stacked. The channel structure includes a first channel layer and a second channel layer. The first channel layer is embedded in the first stack structure and is in contact with the substrate. The second channel layer is located on the first channel layer and is embedded in the second stack structure. The resistance value of the first channel layer is smaller than the resistance value of the second channel layer. The charge storage layer is disposed between the second stack structure and the second channel layer.

Based on the above, in the present invention, dopants in the doped dielectric layer of the first stack structure are diffused into the first channel layer, so that the resistance value of the first channel layer not controlled by the gate (word line) is smaller than the resistance value of the second channel layer controlled by the gate (word line). Therefore, the conductivity of the vertical channel structure of the present invention can be increased, thereby further improving the reliability of the memory device having the vertical channel structure.

In order to make the aforementioned features and advantages of the disclosure more comprehensible, embodiments accompanying figures are described in detail below.

### BRIEF DESCRIPTION OF THE DRAWINGS

FIG. 1A to FIG. 8A are cross-sectional schematic diagrams illustrating a manufacturing process of a memory device according to a first embodiment of the present invention.

FIG. 1B to FIG. 8B are top views of cross sections along lines B-B′ in FIG. 1A to FIG. 8A, respectively.

FIG. 9 is a cross-sectional schematic diagram illustrating a memory device according to a second embodiment of the present invention.

FIG. 10 to FIG. 19 are cross-sectional schematic diagrams illustrating a manufacturing process of a memory device according to a third embodiment of the present invention.

### DESCRIPTION OF EMBODIMENTS

The invention will be described more fully with reference to the drawings of the embodiments. However, the invention can also be embodied in various forms, it should not be limited to the embodiments in this disclosure. The thickness of the layers and the regions in the drawings will be magnified for clarity. The same or similar reference numerals indicate the same or similar elements, it will not be repeated one by one in following paragraphs.

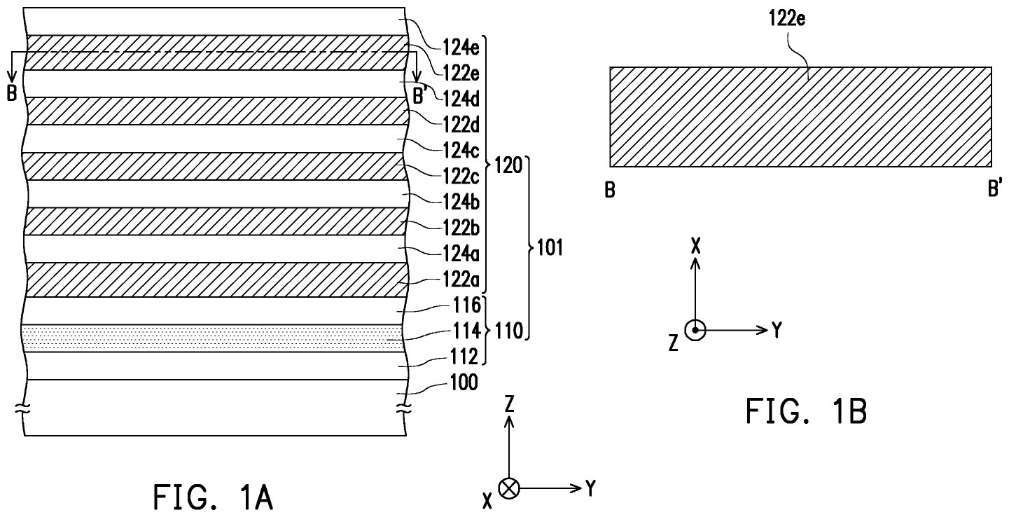

FIG. 1A to FIG. 8A are cross-sectional schematic diagrams illustrating a manufacturing process of a memory device according to a first embodiment of the present invention. FIG. 1B to FIG. 8B are top views of cross sections along lines B-B′ in FIG. 1A to FIG. 8A, respectively. The memory device described in the following embodiments may be a single gate vertical channel (SGVC) NAND memory. However, the invention is not limited thereto.

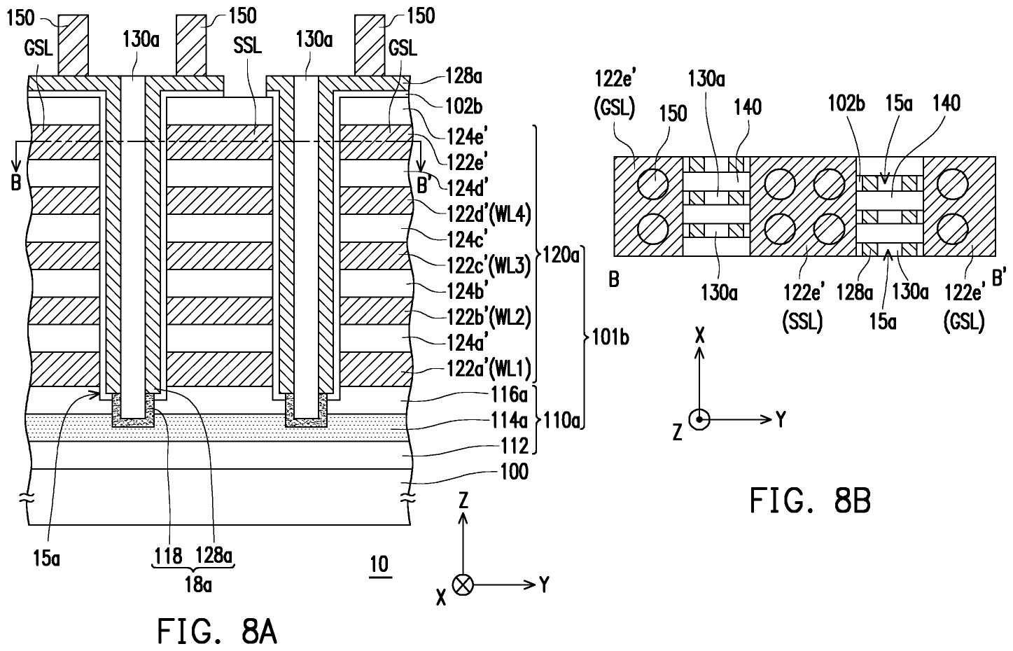

Referring to FIG. 1A and FIG. 1B, a manufacturing method of the memory device 10 (shown in FIG. 8A) of the first embodiment of the present invention is as follows. First, a substrate 100 is provided. In an embodiment, the substrate 100 includes a semiconductor substrate, such as a silicon substrate.

Next, a stack structure 101 is formed on the substrate 100. Specifically, the stack structure 101 includes a first stack structure 110 and a second stack structure 120 located on the first stack structure 110. As shown in FIG. 1A, the first stack structure 110 includes a bottom dielectric layer 112, a doped dielectric layer 114, and a top dielectric layer 116 from bottom to top. The bottom dielectric layer 112 is disposed on the substrate 100 and is in contact with the substrate 100. The top dielectric layer 116 is disposed on the bottom dielectric layer 112. The doped dielectric layer 114 is disposed between the top dielectric layer 116 and the bottom dielectric layer 112. In an embodiment, the materials of the bottom dielectric layer 112, the doped dielectric layer 114, and the top dielectric layer 116 respectively include silicon oxide, silicon nitride, silicon oxynitride, other suitable dielectric material, or a combination thereof. In another embodiment, the material of the doped dielectric layer 114 includes a doped dielectric material, such as borosilicate glass (BSG), phosphosilicate glass (PSG), oxide with plasma doping, oxide with ion-implanted impurity, oxide with surface modification, or a combination thereof. In other embodiments, the material of the bottom dielectric layer 112 and the top dielectric layer 116 includes an undoped dielectric material.

For example, the material of the doped dielectric layer 114 may be an N-type and/or a P-type doped silicon oxide. The material of the bottom dielectric layer 112 and the top dielectric layer 116 may be undoped silicon oxide. In some embodiments, the doping concentration of the doped dielectric layer 114 is greater than the doping concentration of the bottom dielectric layer 112, and greater than the doping concentration of the top dielectric layer 116. In some embodiments, the doped dielectric layer 114 is sandwiched between the bottom dielectric layer 112 and the top dielectric layer 116, the bottom dielectric layer 112 and the top dielectric layer 116 not only can avoid the dopants in the doped dielectric layer 114 out-diffusing, but also can balance the stress of the stack structure 101. In this embodiment, the doping concentration of the doped dielectric layer 114 can be adjusted according to actual demands, and the invention is not limited thereto.

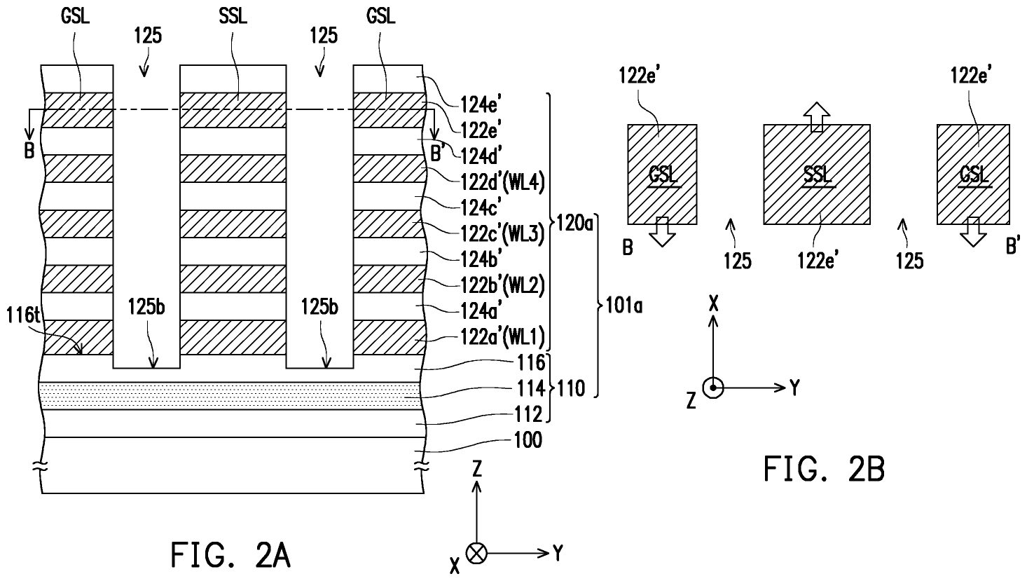

As shown in FIG. 1A, the second stack structure 120 includes a plurality of conductive layers 122a, 122b, 122c, 122d, 122e and a plurality of dielectric layers 124a, 124b, 124c, 124d, 124e which are alternately stacked along the Z direction. In an embodiment, the material of the conductive layers 122a, 122b, 122c, 122d, 122e includes a doped semiconductor material (e.g., silicon, germanium or a combination thereof), a metal material (for example, tungsten, platinum or a combination thereof) and a conductive material (for example, titanium nitride, tantalum nitride, silicon carbide or a combination thereof). In an embodiment, materials of dielectric layers 124a, 124b, 124c, 124d, 124e include silicon oxide, silicon nitride, silicon oxynitride, suitable dielectric materials, or combinations thereof. In some embodiments, the materials of the dielectric layers 124a, 124b, 124c, 124d, 124e may be the same (for example, all are silicon oxide). In another embodiment, the materials of the dielectric layers 124a, 124b, 124c, 124d, 124e may be different from each other. For example, the material of the dielectric layers 124a, 124b, 124c, 124d may be silicon oxide; the material of the topmost dielectric layer 124e may be silicon nitride. When the topmost dielectric layer 124e is a silicon nitride layer, it can be used to provide tensile stress; or as a reinforcing structure for subsequently forming high aspect ratio openings 125 (shown in FIG. 2A), to avoid bending the stack structure 101.

Referring to FIG. 2A and FIG. 2B, openings 125 are formed in the stack structure 101. As shown in FIG. 2A, the openings 125 extend along the Z direction, and through the second stack structure 120 to expose the top dielectric layer 116 of the first stack structure 110. As shown in FIG. 2B, the openings 125 may be strip openings or trench openings 125 extending along the X direction. In an embodiment, the bottom surface 125b of the openings 125 may be lower than or equal to the top surface 116t of the top dielectric layer 116. The number of openings 125 may be plural, and a plurality of openings 125 divide the second stack structure 120 into a plurality of strip-shaped second stack structures 120a. The strip-shaped second stack structures 120a extend along the X direction, and alternately arranged along the Y direction. Specifically, the conductive layers 122a′, 122b′, 122c′, 122d′, 122e′ and the dielectric layers 124a′, 124b′, 124c′, 124d′, 124e′ of the strip-shaped second stack structure 120a are strip structures extending along the X direction. As shown in FIG. 2B, the topmost conductive layer 122e′ may be a string select line SSL or a ground select line GSL. The string selection line SSL and the ground selection line GSL are respectively disposed on both sides of the openings 125, and separated from each other by the openings 125. The conductive layers 122a′, 122U′, 122c′, 122d′ may be word lines WL1, WL2, WL3, WL4. Although FIG. 2A only shows four word lines WL1, WL2, WL3, WL4, however, the invention is not limited thereto. In another embodiment, the number of conductive layers or word lines may be 8 layers, 16 layers, 32 layers, 39 layers, 72 layers or more. In another embodiment, the bottommost conductive layer 122a′ may be an assist gate line. In some embodiments, the thickness of the string selection line SSL and the ground selection line GSL is greater than the thicknesses of the word lines WL1, WL2, WL3, WL4. In another embodiment, when the bottommost conductive layer 122a′ is the assist gate line, the thickness of the assist gate line 122a′ is greater than the thicknesses of other word lines WL2, WL3, WL4.

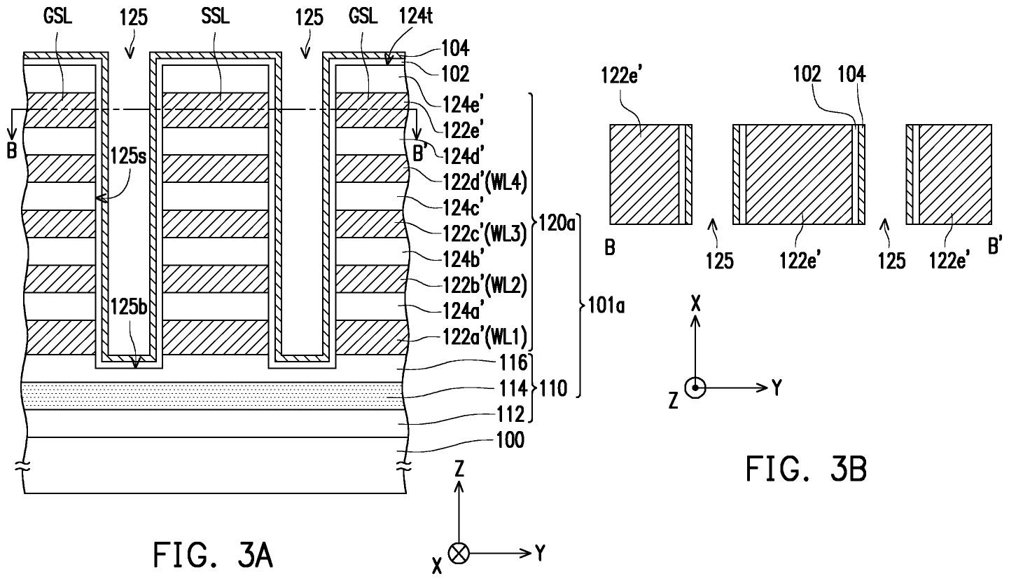

Referring to FIG. 3A and FIG. 3B, a charge storage layer 102 is formed on the substrate 100. Specifically, the charge storage layer 102 conformally covers the sidewalls 125s and 125b of the openings 125 and extends to cover the top surface 124t of the dielectric layer 124e′ of the second stack structure 120a. In an embodiment, the charge storage layer 102 may be a composite layer of oxide/nitride/oxide (ONO), a composite layer of oxide/nitride/oxide/nitride/oxide (ONONO), a composite layer of silicon/oxide/nitride/oxide/silicon (SONOS) or other suitable charge storage material.

Next, the first channel material 104 is formed on the charge storage layer 102. In an embodiment, the first channel material 104 includes a doped semiconductor material, an undoped semiconductor material, or a combination thereof. For example, the first channel material 104 may be an undoped polysilicon. As shown in FIG. 3A, the first channel material 104 conformally extends along the surface of the openings 125, so that the charge storage layer 102 is disposed between the first channel material 104 and the stack structure 101a.

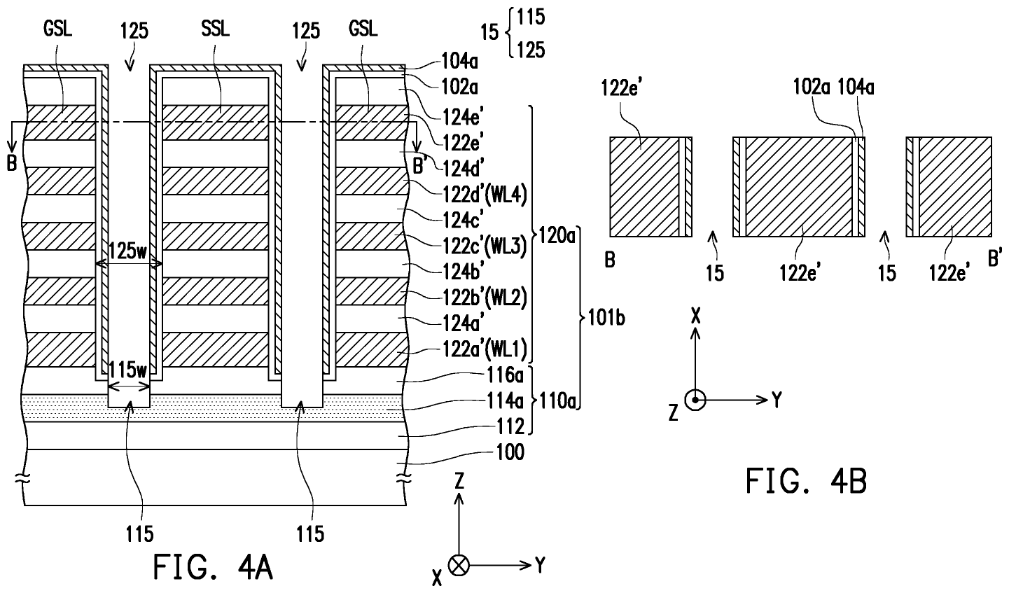

Referring to FIG. 4A and FIG. 4B, a mask pattern (not shown) is formed on the substrate 100. The mask pattern is used as a mask to remove the charge storage layer 102 and the first channel material 104 on the bottom surface 125b of the openings 125 (as shown in FIG. 3A). Next, the remaining charge storage layer 102a and the first channel material 104a are used as a mask, so that portions of the top dielectric layer 116 and the doped dielectric layer 114 are removed to form openings 115 (hereinafter referred to as first openings 115). The first openings 115 are located below the openings 125 (hereinafter referred to as second openings 125). The first openings 115 and the second openings 125 are connected to each other to form the openings 15. In some embodiments, the opening 15 is an opening with a wider upper portion and a narrow lower portion. That is, a width 125w of the second openings 125 is greater than a width 115w of the first openings 115. In an embodiment, the openings 15 at least partially penetrate through the stack structure 101b. Specifically, as shown in FIG. 4A, the openings 15 penetrate through the second stack structure 120a and partially penetrates through the first stack structure 110a to expose the doped dielectric layer 114a of the first stack structure 110a.

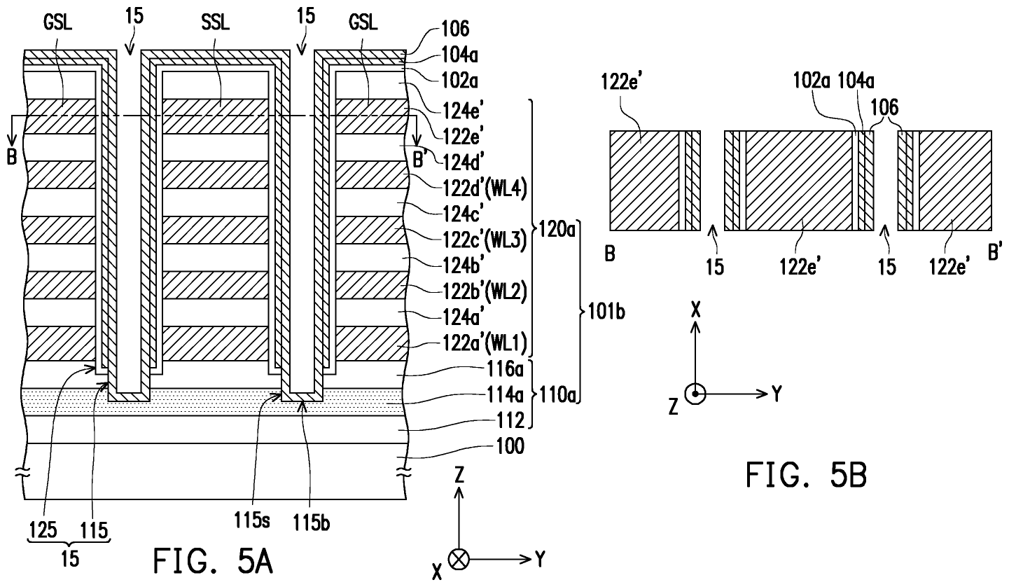

Please referring to FIG. 5A and FIG. 5B, after removing the mask pattern, a second channel material 106 is formed on the substrate 100. As shown in FIG. 5A, the second channel material 106 conformally covers the first channel material 104a and extends to cover the sidewall 115s and the bottom surface 115b of the first openings 115. In an embodiment, the second channel material 106 includes a doped semiconductor material, an undoped semiconductor material, or a combination thereof. For example, the second channel material 106 may be an undoped polysilicon. In some embodiments, the second channel material 106 and the first channel material 104a include the same material. In another embodiment, the second channel material 106 and the first channel material 104a may also include different materials.

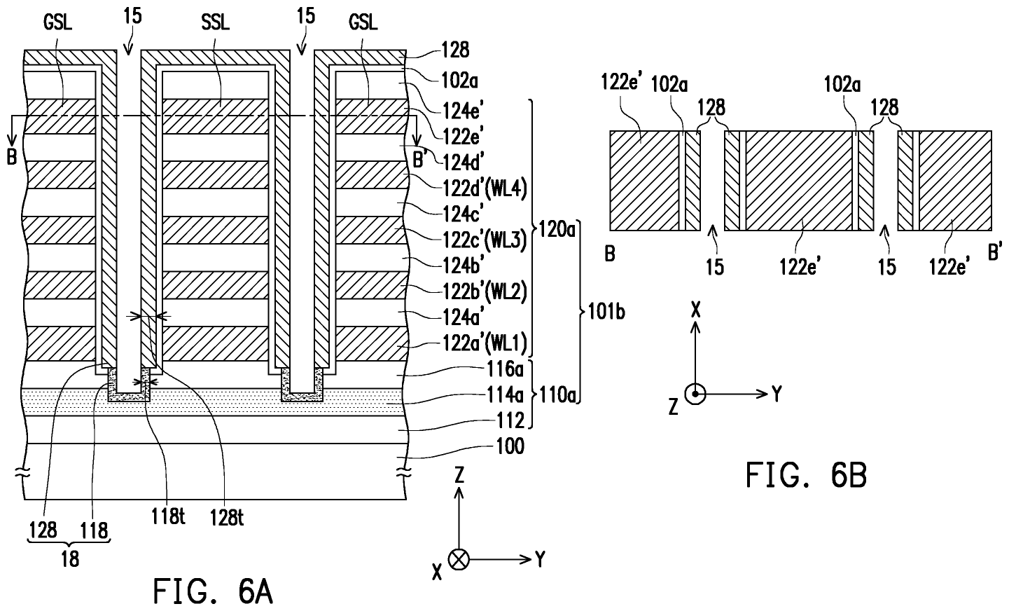

Please referring to FIG. 5A, FIG. 5B, FIG. 6A and FIG. 6B, the annealing process is performed, so that the second channel material 106 that is in contact with the doped dielectric layer 114a is changed to the first channel layer 118. As shown in FIG. 6A, the first channel layer 118 may be a cup-shaped structure or a U-shaped structure, which is embedded in the first stack structure 110a. Specifically, during the annealing process, the dopants of the doped dielectric layer 114a diffuses into the second channel material 106, thereby increasing the doping concentration of the first channel layer 118. That is, when the second channel material 106 is an undoped semiconductor material, after the annealing process, the first channel layer 118 is diffused into a doped semiconductor material. In another embodiment, when the second channel material 106 is a doped semiconductor material, after the annealing process, the doping concentration of the first channel layer 118 may be increased accordingly. That is, the conductivity type of the second channel material 106 is the same as that of the doped dielectric layer 114a.

On the other hand, after the annealing process, the first channel material 104a and the second channel material 106 in contact with each other become the second channel layer 128. In this situation, as shown in FIG. 6A, the first channel layer 118 and the second channel layer 128 may be referred as a continuous channel structure 18. Specifically, the first channel layer 118 is embedded in the first stack structure 110a, and the second channel layer 128 is embedded in the second stack structure 120a. In an embodiment, a thickness 128t of the second channel layer 128 may be greater than a thickness 118t of the first channel layer 118. In an embodiment, the annealing temperature may be from 600° C. to 1000° C., and the annealing time may be between 5 seconds and 120 seconds. However, the invention is not limited thereto, in another embodiment, the process parameters of the annealing process can be adjusted according to actual demands.

It should be noted that the dopants of the doped dielectric layer 114a diffuse into the second channel material 106, so that the doping concentration of the first channel layer 118 is larger than the doping concentration of the second channel layer 128. Therefore, the resistance value of the first channel layer 118 is smaller than the resistance value of the second channel layer 128. In this situation, the first channel layer 118, which is not controlled by the conductive layers or the word lines, can be considered as the normally-on state. That is, compared to conventional undoped channel layers, the doped first channel layer 118 of the present embodiment has better conductivity.

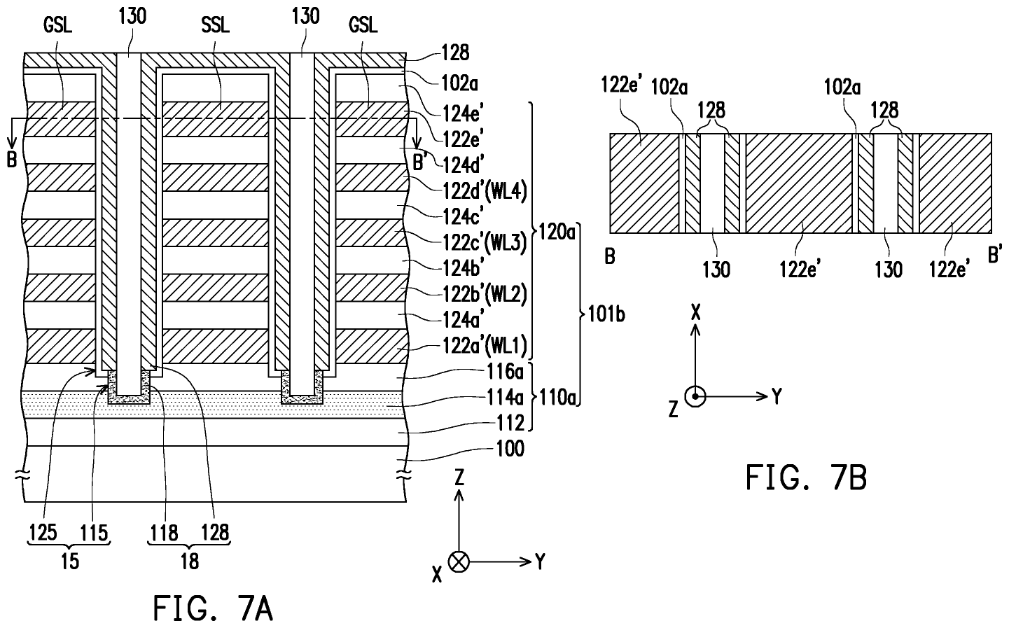

Referring to FIG. 7A and FIG. 7B, a dielectric structure 130 is formed in the openings 15, such that the channel structure 18 (which includes the first channel layer 118 and the second channel layer 128) is formed to cover the bottom surface and sidewalls of the dielectric structure 130. Specifically, a dielectric material (not shown) is formed on the substrate 100. In some embodiments, the dielectric material includes silicon oxide, silicon nitride, silicon oxynitride or a combination thereof. The dielectric material is filled into the openings 15 (which includes the first openings 115 and the second openings 125), and extends to cover the top surface of the second channel layer 128. A planarization process is then performed to expose the top surface of the second channel layer 128. In this situation, as shown in FIG. 7A, the top surface of the dielectric structure 130 and the top surface of the second channel layer 128 are considered as coplanar. In an embodiment, the planarization process may be a chemical mechanical polishing (CMP) process. In addition, although the dielectric structure 130 illustrated in FIG. 7A is completely filled in the openings 15, however, the invention is not limited thereto. In another embodiment, the dielectric structure 130 may also have an air gap therein.

Referring to FIGS. 7A, 7B, 8A, and 8B, the second channel layer 128 and the charge storage layer 102a are patterned, and a plurality of isolation structures 140 are then formed in the stack structure 101b. In an embodiment, the material of the isolation structure 140 includes silicon oxide, silicon nitride, silicon oxynitride, other suitable dielectric materials or a combination thereof. As shown in FIG. 8A, the isolation structure 140 may be a pillar structure extending along the Z direction. The isolation structures 140 divide the strip openings 15 into island openings 15a, such that the second channel layer 128a in one of the openings 15a is electrically isolated from the second channel layer 128a in another of the openings 15a. In addition, the dielectric structure 130 is also separated into a plurality of dielectric pillars 130a by the isolation structure 140. In an embodiment, as shown in FIG. 8B, the isolation structures 140 on both sides of the string selection line SSL and/or the ground selection line GSL is a staggered configuration. However, the invention is not limited thereto. In another embodiment, the isolation structures 140 on both sides of the string selection line SSL and/or the ground selection line GSL may also correspond to each other.

In this situation, as shown in FIG. 8A, the channel structure 18a (which includes the first channel layer 118 and the second channel layer 128a) disposed in the openings 15a may be considered as a vertical channel structure. The channel structure 18a penetrates through the second stack structure 120a and partially penetrates through the first stack structure 110a, so as to be in contact with the doped dielectric layer 114a of the first stack structure 110a. Therefore, the dopants in the doped dielectric layer 114a can diffuse into the first channel layer 118, so that the resistance value of the first channel layer 118 not controlled by the conductive layers (gates) 122a′, 122b′, 122c′, 122d′, 122e′ is smaller than the resistance value of the second channel layer 128a controlled by the conductive layers (gates) 122a′, 122b′, 122c′, 122d′, 122e′. As a result, the conductivity of the vertical channel structure 18a of the present embodiment can be increased, thereby improving the reliability of the memory device 10 having the vertical channel structure 18a. On the other hand, a portion of the charge storage layer 102b is disposed between the second stack structure 120a and the second channel layer 128a, and another portion of the charge storage layer 102b is disposed between the first stack structure 110a and the first channel layer 118 and/or the second channel layer 128. The dielectric post 130a is disposed in the openings 15a, such that the channel structure 18a covers the bottom surface and sidewalls of the dielectric post 130a.

In addition, after the isolation structure 140 is formed, a plurality of conductive plugs 150 is further formed on the second channel layer 128a on both sides of the openings 15a. In an embodiment, the material of the conductive plugs 150 includes a metal, a barrier metal, a polysilicon or a combination thereof. The formation method includes chemical vapor deposition (CVD) or physical vapor deposition (PVD).

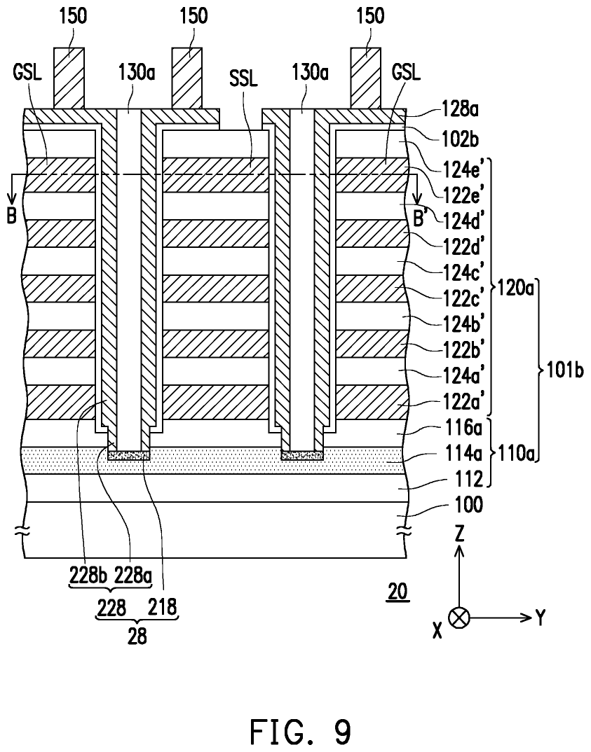

FIG. 9 is a cross-sectional schematic diagram illustrating a memory device according to a second embodiment of the present invention.

Please referring to FIG. 9, basically, the memory device 20 of the second embodiment is similar to the memory device 10 of the first embodiment. A difference therebetween lies in that the first channel layer 118 of the memory device 10 is a cup-shaped structure or a U-shaped structure and the first channel layer 218 of the memory device 20 is a strip structure or a linear structure. Other components of the memory device 20 of the second embodiment have been described in the above paragraphs, they will not be repeated here.

In addition, a thickness of the lower portion 228a of the second channel layer 228 embedded in the first stack structure 110a is smaller than a thickness of the upper portion 228a of the second channel layer 228 embedded in the second stack structure 120a. As shown in FIG. 9, the channel structure 28 having the first channel layer 218 and the second channel layer 228 may be considered as a vertical channel structure. The channel structure 28 penetrates through the second stack structure 120a and partially penetrates through the first stack structure 110a to be in contact with the doped dielectric layer 114a of the first stack structure 110a. Therefore, the dopants in the doped dielectric layer 114a can diffuse into the first channel layer 218, such that the resistance value of the first channel layer 218 not controlled by the conductive layers (gates) 122a′, 122b′, 122c′, 122d′, 122e′ is smaller than the resistance value of the second channel layer 228 controlled by the conductive layers (gates) 122a′, 122b′, 122c′, 122d′, 122e′. As a result, the conductivity of the vertical channel structure 28 of the present embodiment can be increased, thereby improving the reliability of the memory device 20 having the vertical channel structure 28.

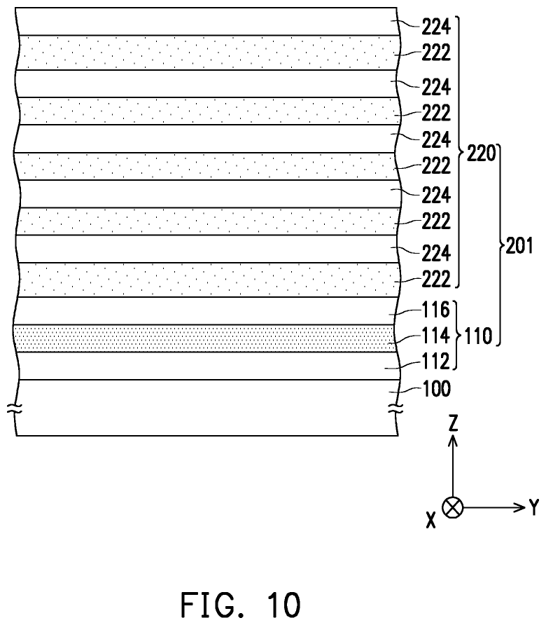

FIG. 10 to FIG. 19 are cross-sectional schematic diagrams illustrating a manufacturing process of a memory device according to a third embodiment of the present invention. The memory device described in the following embodiments may be a gate-all-around (GAA) NAND memory. However, the invention is not limited thereto.

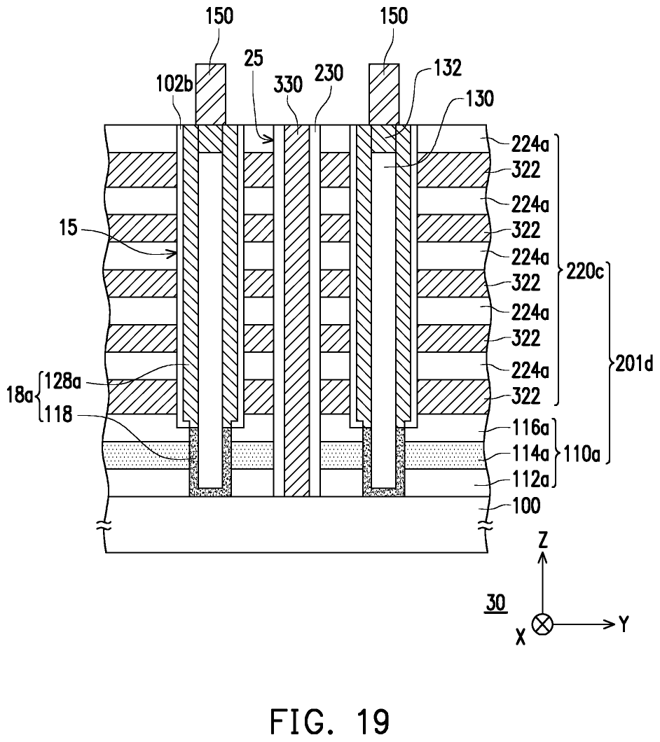

Please referring to FIG. 10, the manufacturing method of the memory device 30 (shown in FIG. 19) of the third embodiment of the present invention is as below. First, the substrate 100 is provided. In an embodiment, the substrate 100 includes a semiconductor substrate, such as a silicon substrate.

Next, a stack structure 201 is formed on the substrate 100. Specifically, the stack structure 201 includes a first stack structure 110 and a second stack structure 220 located on the first stack structure 110. The configuration, material, and formation method of the first stack structure 110 have been described in the above paragraphs, and it will not be repeated here.

The second stack structure 220 includes a plurality of first materials 222 and a plurality of second materials 224 stacked on each other. In an embodiment, the first materials 222 and the second materials 224 may be different dielectric materials. For example, the first materials 222 may be silicon nitride, and the second materials 224 may be silicon oxide. However, the invention is not limited thereto. In another embodiment, the first materials 222 may be polysilicon and the second materials 224 may be silicon oxide. Although FIG. 10 only shows five layers of first material 222 and five layers of second material 224. However, the invention is not limited thereto. In another embodiment, the number of the first materials 222 and the second materials 224 may be 8 layers, 16 layers, 32 layers, 39 layers, 72 layers or more.

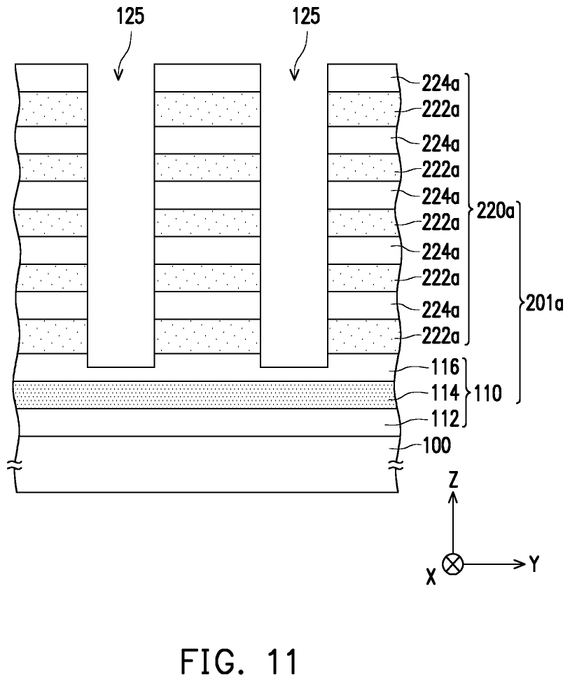

Please referring to FIG. 11, openings 125 are formed in the stack structure 201a. Specifically, the openings 125 may be strip openings or trenches extending along the X direction. As shown in FIG. 11, the openings 125 penetrate through the second stack structure 220 and exposes the top dielectric layer 116 of the first stack structure 110.

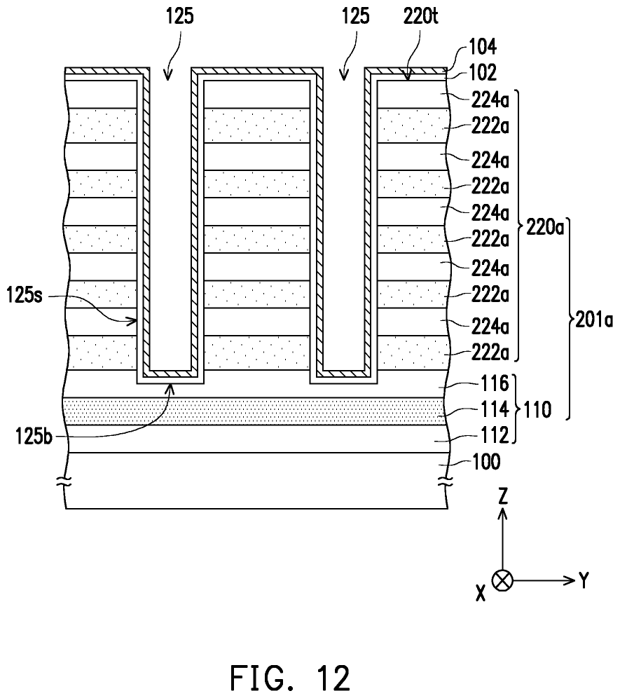

Please referring to FIG. 11 and FIG. 12, a charge storage layer 102 is formed on the substrate 100. Specifically, the charge storage layer 102 conformally covers the sidewall 125s and the bottom surface 125b of the openings 125 and extends to cover the top surface 220t of the second stack structure 220a. In an embodiment, the charge storage layer 102 may be a composite layer of oxide/nitride/oxide (ONO), a composite layer of oxide/nitride/oxide/nitride/oxide (ONONO), a composite layer of silicon/oxide/nitride/oxide/silicon (SONOS) or other suitable charge storage material.

Next, a first channel material 104 is forming on the charge storage layer 102. In an embodiment, the first channel material 104 includes a doped semiconductor material, an undoped semiconductor material, or a combination thereof. For example, the first channel material 104 may be an undoped polysilicon. As shown in FIG. 12, the first channel material 104 conformally extends along the surface of the openings 125, and covers the top surface 220t of the second stack structure 220a.

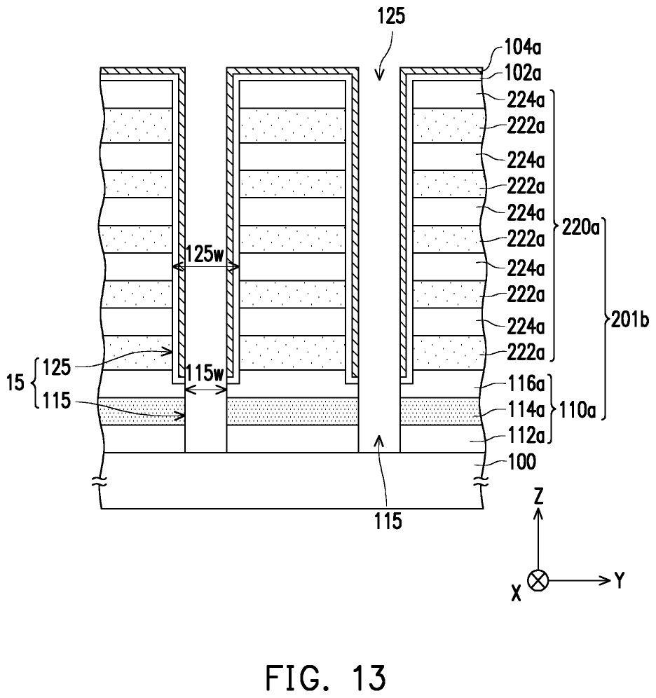

Please referring to FIG. 12 and FIG. 13, a mask pattern (not shown) is formed on the substrate 100. The mask pattern is used as a mask to remove the charge storage layer 102 and the first channel material 104 on the bottom surface 125b of the openings 125 (as shown in FIG. 12). Next, the remaining charge storage layer 102a and the first channel material 104a are used as a mask, so that a portion of the top dielectric layer 116, a portion of the doped dielectric layer 114, and a portion of the bottom dielectric layer 112 are removed to form openings 115 (hereinafter referred to as first openings 115). The first openings 115 is located below the openings 125 (hereinafter referred to as second openings 125). The first openings 115 and the second openings 125 are connected to each other to form the openings 15. In some embodiments, the openings 15 is an opening with a wider upper portion and a narrow lower portion. That is, the width 125w of the second openings 125 is greater than the width 115w of the first openings 115. As shown in FIG. 4A, the openings 15 penetrates through the stack structure 201b to expose the substrate 100.

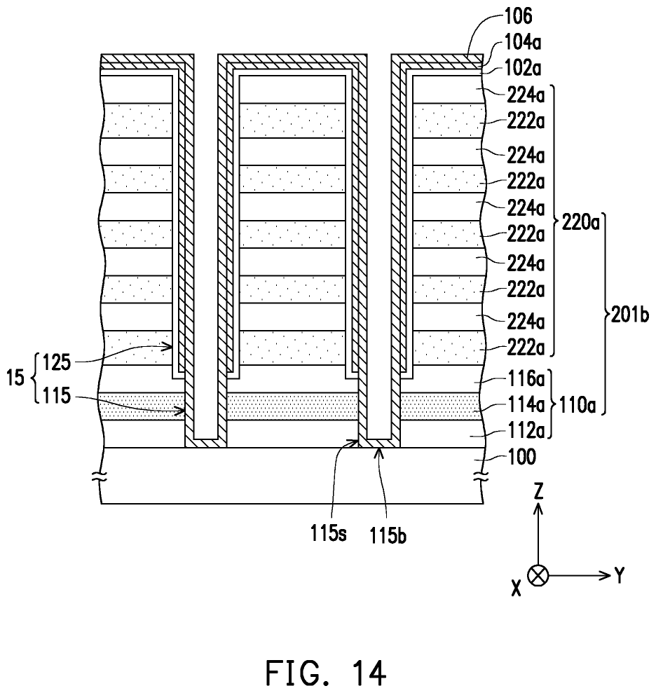

Please referring to FIG. 14, after removing the mask pattern, a second channel material 106 is formed on the substrate 100. As shown in FIG. 14, the second channel material 106 conformally covers the first channel material 104a and extends to cover the sidewall 115s and the bottom surface 115b of the first openings 115. In an embodiment, the second channel material 106 includes a doped semiconductor material, an undoped semiconductor material, or a combination thereof. For example, the second channel material 106 may be an undoped polysilicon. In some embodiments, the second channel material 106 and the first channel material 104a include the same material. In another embodiment, the second channel material 106 and the first channel material 104a may also include different materials.

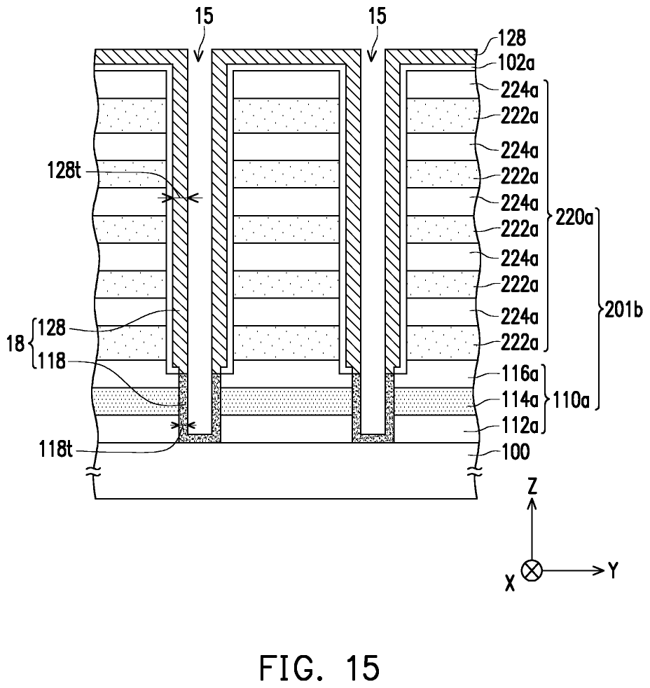

Please referring to FIG. 15, the annealing process is performed, such that the second channel material 106 that is in contact with the doped dielectric layer 114a is changed to the first channel layer 118. As shown in FIG. 15, the first channel layer 118 may be a cup-shaped structure or a U-shaped structure embedded in the first stack structure 110a. Specifically, during the annealing process, the dopants of the doped dielectric layer 114a diffuse into the second channel material 106, such that the doping concentration of the first channel layer 118 is increased. That is, when the second channel material 106 is an undoped semiconductor material, after the annealing process, the first channel layer 118 is then diffused into a doped semiconductor material. In another embodiment, when the second channel material 106 is a doped semiconductor material, after the annealing process, the doping concentration of the first channel layer 118 is increased accordingly. That is, the conductivity type of the second channel material 106 is the same as that of the doped dielectric layer 114a.

On the other hand, after the annealing process, the first channel material 104a and the second channel material 106 in contact with each other become the second channel layer 128. In this situation, as shown in FIG. 15, the first channel layer 118 and the second channel layer 128 may be considered as a continuous channel structure 18. Specifically, the first channel layer 118 is embedded in the first stack structure 110a and is in contact with the substrate 100, and the second channel layer 128 is embedded in the second stack structure 220a. In an embodiment, the thickness 128t of the second channel layer 128 may be greater than the thickness 118t of the first channel layer 118. In an embodiment, the annealing temperature may be from 600° C. to 1000° C. and the annealing time may be between 5 seconds and 120 seconds. However, the invention is not limited thereto. In another embodiment, the process parameters of the annealing process can be adjusted according to actual demands.

It should be noted that the dopants of the doped dielectric layer 114a diffuse into the second channel material 106, so that the doping concentration of the first channel layer 118 is larger than the doping concentration of the second channel layer 128. Therefore, the resistance value of the first channel layer 118 is smaller than the resistance value of the second channel layer 128. In this situation, the first channel layer 118, which is not controlled by the conductive layers or word lines, may be considered as the normally-on state. That is, compared to conventional undoped channel layers, the doped first channel layer 118 of the present embodiment has better conductivity.

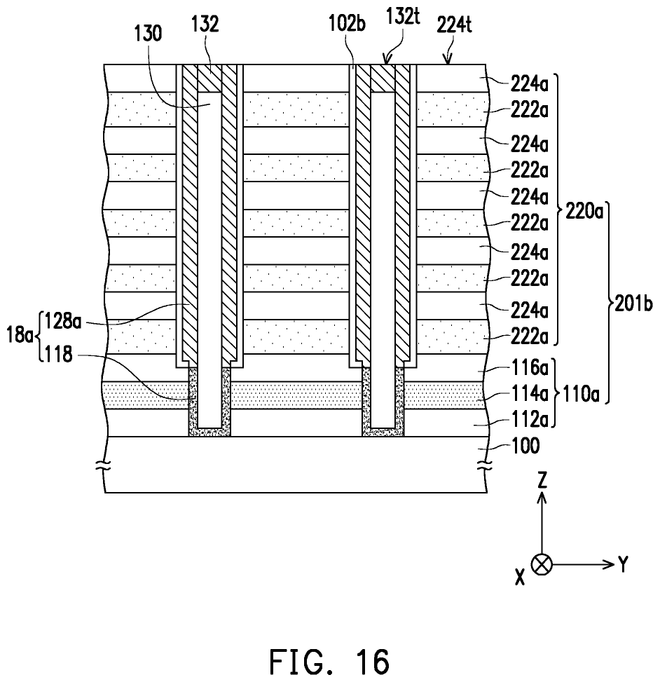

Please referring to FIG. 15 and FIG. 16, a dielectric structure 130 is formed in openings 15, such that the channel structure 18a (which includes the first channel layer 118 and the second channel layer 128a) is formed to cover the bottom surface and sidewalls of the dielectric structure 130. Next, a sealing layer 132 is formed on the substrate 100 to cover the top surface of the dielectric structure 130. In an embodiment, the material of the sealing layer 132 includes a doped semiconductor material, an undoped semiconductor material, or a combination thereof. In another embodiment, the material of the sealing layer 132 may be the same as or different from the material of the second channel layer 128a. The method of forming the sealing layer 132 includes forming a sealing material (not shown) on the substrate 100 blanketly. A planarization process is then performed to expose the top surface 224t of the topmost second material 224a. In this situation, as shown in FIG. 16, the top surface 132t of the sealing layer 132 is coplanar with the top surface 224t of the topmost second material 224a. In addition, a portion of the charge storage layer 102b is disposed between the second stack structure 220a and the second channel layer 128, and another portion of the charge storage layer 102b is disposed between the first stack structure 110a and the first channel layer 118 and/or the second channel layer 128a.

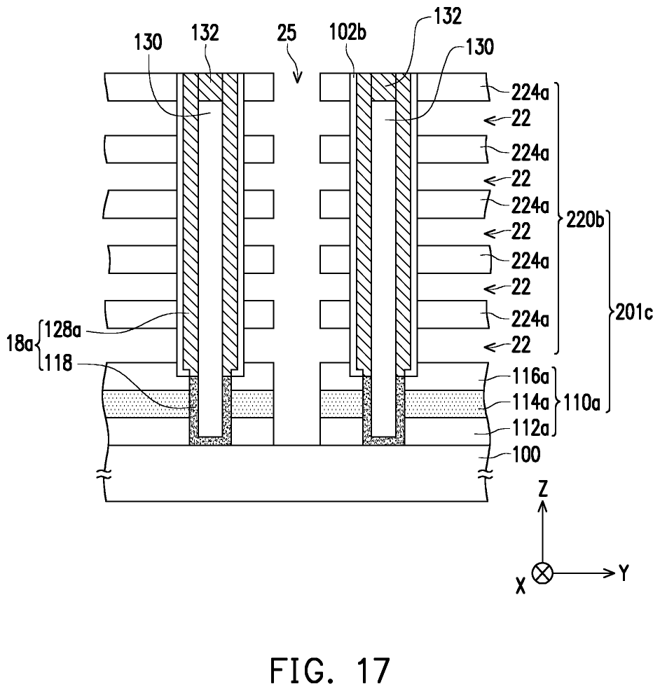

Please referring to FIG. 16 and FIG. 17, a slit 25 is formed in the stack structure 201c between the adjacent two channel structures 18a. The slit 25 penetrates through the second stack structure 220b and the first stack structure 110a to expose the substrate 100. Although the bottom surface of the slit 25 illustrated in FIG. 17 is coplanar with the bottom surface of the first stack structure 110a. However, during forming the slit 25, a part of the substrate 100 is also removed in order to completely remove the bottom dielectric layer 112a of the first stack structure 110a. In this situation, the bottom surface of the slit 25 may be lower than the top surface of the substrate 100.

After forming the slit 25, the etching process is performed to remove the first materials 222a, so as to form a plurality of voids 22 between the second materials 224a. The void 22s laterally exposes a portion of the sidewalls of the charge storage layer 102b. That is, the voids 22 are defined by the second materials 224a and the charge storage layer 102a. In an embodiment, the etching process may be a wet etching process. For example, when the first materials 222a are silicon nitride, the etching process may be using an etching solution containing phosphoric acid, and pouring the etching solution into the slit 25, thereby removing the first material 222a. Since the etching solution has high etching selectivity with respect to the first materials 222a, the first materials 222a may be completely removed, and the second materials 224a may be not removed or only few second materials 224a are removed.

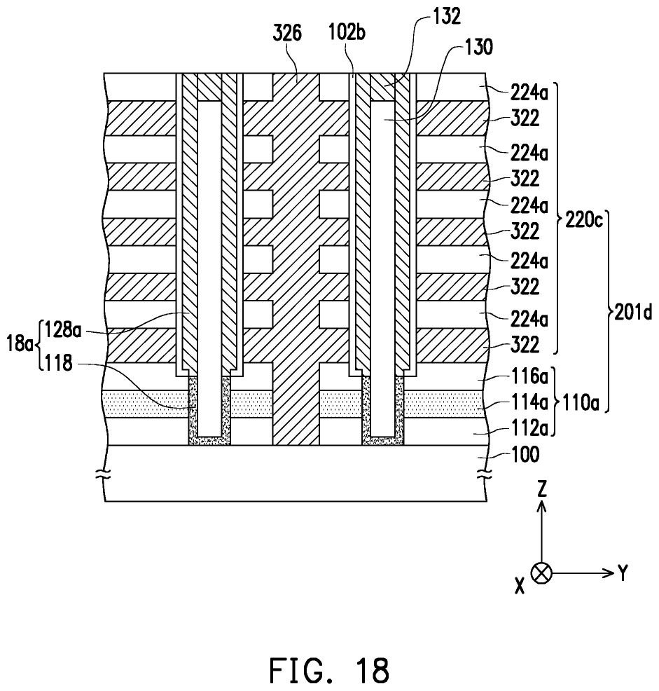

Please referring to FIG. 17 and FIG. 18, conductive layers 322 are formed in the voids 22 and a conductive layer 326 is formed in the slit 25. In an embodiment, the material of the conductive layers 322, 326 includes a metal (e.g., tungsten, platinum or a combination thereof), a barrier metal (e.g., TiN, TaN or a combination thereof) or a combination thereof, and the formation method may be CVD or PVD.

Please referring to FIG. 18 and FIG. 19, the conductive layer 326 in the slit 25 is removed. Then, a dielectric layer 230 is formed in slit 25 to cover the sidewall of the slit 25. In an embodiment, the material of the dielectric layer 230 may be silicon oxide, silicon nitride, silicon oxynitride, suitable dielectric materials, or a combination thereof. After that, a conductive pillar 330 is formed in the slit 25, such that the dielectric layer 230 is disposed between the conductive pillar 330 and the stack structure 201d. In an embodiment, the material of the conductive pillar 330 includes a metal, a barrier metal, a polysilicon or a combination thereof. Then, a plurality of conductive plugs 150 are formed on the sealing layer 132.

In this situation, as shown in FIG. 19, the conductive pillar 330 penetrates through the stack structure 201d (which includes the first stack structure 110a and the second stack structure 220c) and is in contact with the substrate 100 to form a common source line (CSL). In an embodiment, the conductive layers 322 may be word lines, which surround the vertical channel structure 18a to form the gate-all-around (GAA) memory device 30.

It should be noted that, as shown in FIG. 19, the channel structure 18a (which includes the first channel layer 118 and the second channel layer 128a) disposed in the openings 15 may be considered as a vertical channel structure. The channel structure 18a penetrates through the second stack structure 220c and the first stack structure 110a to be in contact with the doped dielectric layer 114a of the first stack structure 110a. Therefore, the dopants in the doped dielectric layer 114a can diffuse into the first channel layer 118, such that the resistance value of the first channel layer 118 that is not controlled by the conductive layer (gate) 322 is smaller than the resistance value of the second channel layer 128a controlled by the conductive layer (gate) 322. As a result, the conductivity of the vertical channel structure 18a of the present embodiment can be increased, thereby improving the reliability of the memory device 30 having the vertical channel structure 18a.

In summary, in the present invention, dopants in the doped dielectric layer of the first stack structure are diffused into the first channel layer, such that the resistance value of the first channel layer not controlled by the gate (word line) is smaller than the resistance value of the second channel layer controlled by the gate (word line). Accordingly, the conductivity of the vertical channel structure of the present invention can be increased, thereby improving the reliability of the memory device having the vertical channel structure.

Although the invention has been disclosed by the above embodiments, the embodiments are not intended to limit the invention. It will be apparent to those skilled in the art that various modifications and variations can be made to the structure of the invention without departing from the scope or spirit of the invention. Therefore, the protecting range of the invention falls in the appended claims.

1. A vertical channel structure, comprising:
a stack structure disposed on a substrate; and
a channel structure disposed in an opening at least partially penetrating the stack structure, the channel structure comprising:
a first channel layer disposed on a bottom of the opening; and
a second channel layer located on the first channel layer, wherein a resistance value of the first channel layer is smaller than a resistance value of the second channel layer.

2. The vertical channel structure according to claim 1, wherein the stack structure includes:
a first stack structure, wherein the first stack structure includes:
a bottom dielectric layer disposed on the substrate;
a top dielectric layer disposed on the bottom dielectric layer; and
a doped dielectric layer disposed between the top dielectric layer and the bottom dielectric layer, wherein a doping concentration of the doped dielectric layer is greater than doping concentrations of the top dielectric layer and the bottom dielectric layer; and
a second stack structure disposed on the first stack structure, wherein the second stack structure comprises a plurality of conductive layers and a plurality of dielectric layers alternately stacked.

3. The vertical channel structure according to claim 2, wherein the opening exposes the doped dielectric layer of the first stack structure.

4. The vertical channel structure according to claim 2, wherein the opening exposes the substrate.

5. The vertical channel structure according to claim 2, wherein the opening comprises:
a first opening disposed in the first stack structure; and
a second opening disposed on the first opening and connected to the first opening, wherein a width of the second opening is greater than a width of the first opening.

6. The vertical channel structure according to claim 1, further comprising:
a dielectric pillar disposed in the opening, wherein the channel structure covers a bottom surface and a sidewall of the dielectric pillar; and
a charge storage layer disposed between the stack structure and the second channel layer.

7. The vertical channel structure according to claim 1, wherein a material of the first channel layer comprises a doped semiconductor material, and a material of the second channel layer comprises an undoped semiconductor material.

8. The vertical channel structure according to claim 1, wherein materials of the first channel layer and the second channel layer comprise a doped semiconductor material, a doping concentration of the first channel layer is greater than a doping concentration of the second channel layer.

9. A memory device, comprising:
a first stack structure disposed on a substrate;
a second stack structure disposed on the first stack structure, wherein the second stack structure comprises a plurality of conductive layers and a plurality of dielectric layers alternately stacked;
a channel structure, comprising:
a first channel layer embedded in the first stack structure; and
a second channel layer located on the first channel layer and embedded in the second stack structure, wherein a resistance value of the first channel layer is smaller than a resistance value of the second channel layer; and
a charge storage layer disposed between the second stack structure and the second channel layer.

10. The memory device according to claim 9, the first stack structure comprising:
a bottom dielectric layer disposed on the substrate;
a top dielectric layer disposed on the bottom dielectric layer; and
a doped dielectric layer disposed between the top dielectric layer and the bottom dielectric layer, wherein a doping concentration of the doped dielectric layer is greater than doping concentrations of the top dielectric layer and the bottom dielectric layer.

11. The memory device according to claim 10, wherein the first channel layer contacts the doped dielectric layer.

12. The memory device according to claim 10, wherein a thickness of the second channel layer is greater than a thickness of the first channel layer.

13. The memory device according to claim 9, further comprising a dielectric pillar disposed on the channel structure, wherein the channel structure covers a bottom surface and a sidewall of the dielectric pillar.

14. The memory device according to claim 9, wherein a material of the first channel layer comprises a doped semiconductor material, and a material of the second channel layer comprises an undoped semiconductor material.

15. The memory device according to claim 9, wherein materials of the first channel layer and the second channel layer comprise a doped semiconductor material, a doping concentration of the first channel layer is greater than a doping concentration of the second channel layer.

16. A memory device, comprising:
a first stack structure disposed on a substrate;
a second stack structure disposed on the first stack structure, wherein the second stack structure comprises a plurality of conductive layers and a plurality of dielectric layers alternately stacked;
a channel structure comprising:
a first channel layer embedded in the first stack structure and in contact with the substrate; and
a second channel layer located on the first channel layer and embedded in the second stack structure, wherein a resistance value of the first channel layer is smaller than a resistance value of the second channel layer; and
a charge storage layer disposed between the second stack structure and the second channel layer.

17. The memory device according to claim 16, wherein the first stack structure includes:
a bottom dielectric layer disposed on the substrate;
a top dielectric layer disposed on the bottom dielectric layer; and
a doped dielectric layer disposed between the top dielectric layer and the bottom dielectric layer, wherein a doping concentration of the doped dielectric layer is greater than doping concentrations of the top dielectric layer and the bottom dielectric layer.

18. The memory device according to claim 16, wherein a thickness of the second channel layer is greater than a thickness of the first channel layer.

19. The memory device according to claim 16, further comprising a conductive pillar between adjacent two channel structures, wherein the conductive pillar penetrates through the second stack structure and the first stack structure, so as to contact the substrate.

20. The memory device according to claim 16, further comprising:
a dielectric pillar disposed on the channel structure, wherein the channel structure covers a bottom surface and a sidewall of the dielectric pillar; and
a sealing layer covering a top surface of the dielectric pillar.
